(19) United States
(12) Patent Application Publication
(10) Pub. No.: US 2026/0040848 A1
(43) Pub. Date: Feb. 5, 2026

(54) METHOD FOR FORMING A HIGH-K METAL OXIDE

(71) Applicant: PENTAPRO MATERIALS INC., Hsinchu County (TW)

(72) Inventors: Wen-Che Kuo, Hsinchu County (TW); Wen-Lian Lee, Hsinchu County (TW); Pi-Chun Juan, Hsinchu County (TW); Pak-Man Yiu, Hsinchu County (TW)

(21) Appl. No.: 19/031,877

(22) Filed: Jan. 18, 2025

(30) Foreign Application Priority Data
Aug. 2, 2024 (TW) 113129085

(51) Int. Cl. H01L 21/02; H01L 21/324

(52) U.S. Cl. CPC H01L 21/02181; H01L 21/02205; H01L 21/0228; H01L 21/324

(57) ABSTRACT

The present invention provides a method for forming a high-k metal oxide. By using a small amount of a precursor mainly composed of trisilyl amine (TSA, chemical formula: N(SiH3)3) to generate silicon dioxide (SiO2), and incorporating it into a high-k metal oxide with an organometallic compound as its precursor, a high-performance high-k metal oxide with a good interface layer to the substrate is formed. This approach effectively prevents leakage in a metal-insulator-semiconductor (MIS) structure and achieves a transistor gate oxide layer with high dielectric constant, low leakage current, high breakdown voltage, and high reliability, while also lowering production costs.

### FIELD OF THE DISCLOSURE

The present invention belongs to the technical field of semiconductor manufacturing and is particularly suitable for solutions relating to forming a high dielectric constant (high-k) metal oxide thin film for use as a transistor gate oxide layer.

### BACKGROUND OF THE INVENTION

In the semiconductor manufacturing field moving toward the nanometer scale, how to fabricate a high-quality, high-dielectric-constant gate oxide layer has become a crucial technology. Because the dielectric constants of conventional silicon dioxide (SiO₂) and silicon nitride (Si₃N₄) are insufficient to meet the gate dielectric constant requirements of current nanometer-scale complementary metal-oxide-semiconductor (CMOS) processes, using metal oxides with even higher dielectric constants as the gate dielectric layer has become an unavoidable choice.

Taking hafnium dioxide (HfO₂) as the most commonly used high-k material today, a typical approach is to deposit a monolayer of an organometallic precursor containing HfO₂, such as tetrakis(ethylmethylamino)hafnium (TEMAH) or tetrakis(dimethylamido)hafnium (TDMAH), on a standard cleaned silicon wafer using atomic layer deposition (ALD). The wafer is then heated to a specific reaction temperature in an oxygen-containing environment (e.g., water (H₂O), ozone (O₃), or oxygen plasma) to form a HfO₂ thin film on the surface of the silicon wafer. By repeating this cycle, HfO₂ is deposited to the required thickness. However, during subsequent high-temperature heat treatment, the oxygen in HfO₂ may diffuse with the silicon atoms in the substrate (if the substrate is silicon), forming a non-uniformly coated SiO₂ or silicate (MxSiyOz) interfacial layer at the Si/HfO₂ interface. Because this interfacial layer is of poor quality, it causes leakage and affects the crystallization behavior of HfO₂, significantly reducing its effective dielectric constant (k-value).

Consequently, a current method of improvement is to use in-situ steam generation (ISSG) by introducing ozone or steam to first form a highly dense, extremely thin, and uniformly coated high-quality SiO₂ layer on the surface of the silicon wafer, followed by depositing HfO₂. This highly dense SiO₂ layer effectively blocks the diffusion between HfO₂ and the substrate silicon, improving its effective dielectric constant. However, the ISSG process technology and equipment are expensive, and the additional high-temperature combustion reaction raises production costs. Therefore, how to simplify the manufacturing of a high-k metal gate oxide layer and reduce production costs is of significant concern in this technical field.

### SUMMARY OF THE INVENTION

The present invention uses a small amount of trisilyl amine (TSA, chemical formula N(SiH₃)₃) to generate SiO₂, which is incorporated into a high-k metal oxide (taking HfO₂ as an example) with an organometallic compound precursor such as TEMAH or TDMAH. The dopant species—SiO₂—relies on TSA as its precursor, and is deposited under an oxygen source environment (e.g., water (H₂O), ozone (O₃), or oxygen plasma) via ALD (atomic layer deposition) or CVD (chemical vapor deposition). In so doing, SiO₂ and HfO₂ are either mixed or stacked, eventually forming a silicon-doped HfO₂ oxide. A subsequent high-temperature annealing step then promotes the movement of the silicon/oxygen atoms originally doped in the film to the interface between the silicon substrate and HfO₂, thus creating a high-quality interfacial SiO₂ layer. This effectively blocks the mutual diffusion of HfO₂ and the substrate, eliminating the conventional ISSG process flow that first forms a SiO₂ barrier layer and then deposits HfO₂. This not only simplifies process complexity but also obtains a gate dielectric layer with a high effective dielectric constant.

Alternatively, one may only adopt an ALD technique to deposit high-quality SiO₂ on the standard-cleaned silicon substrate surface using TSA as a precursor. Next, using the same ALD equipment, one deposits the high-k metal oxide. This method simplifies the fabrication flow as it avoids transitioning to different types of equipment (like ISSG) to create an ultra-thin SiO₂ layer on the substrate.

This method may also be applied to a dynamic random-access memory (DRAM) capacitor dielectric layer to control leakage current and increase the dielectric constant. Currently, whether for DRAM capacitor dielectric layers or for transistor gate oxide dielectric layers, the trend is toward high-k metal oxides such as HfO₂, ZrO₂, La₂O₃, Al₂O₃ binary oxides, or these oxides with metal doping (Al, Zr, Si, lanthanides) to form ternary oxides. For instance, doping with aluminum serves primarily to help HfO₂ form a higher dielectric constant crystal phase (orthorhombic) or to suppress crystallinity to inhibit grain boundary leakage. However, Al doping can trigger an interdiffusion reaction between aluminum and the silicon substrate during high-temperature annealing, leading to spiking and thus leakage, lowering the overall effective capacitance. Therefore, the current solution is still to form a high-quality SiO₂ barrier layer on the surface of the silicon wafer first, followed by a high-performance metal oxide dielectric layer. The present method is likewise suitable for DRAM capacitor processes using high-k metal oxides, allowing a high-quality interfacial SiO₂ layer to form naturally between the metal oxide and the silicon substrate to prevent leakage in the metal oxide dielectric layer. The capacitor thus retains its charge and the overall effective dielectric constant is enhanced.

To make the above features and advantages of the present invention more apparent and understandable, a preferred embodiment is exemplified below, in conjunction with the accompanying drawings, for detailed description.

### BRIEF DESCRIPTION OF THE DRAWINGS

Below, the present invention and its differences from conventional technology will be described based on the drawings and various embodiments. The drawings are provided for illustrative purposes only, not to limit the scope in any way, wherein similar reference numerals refer to similar components, and in which:

FIGS. 1A and 1B are schematic diagrams of an atomic layer deposition system and its process.

FIGS. 2A to 2E are schematic views showing a conventional method for forming a metal oxide dielectric layer.

FIGS. 3A to 3D are schematic views illustrating the manufacturing method for depositing a metal oxide dielectric layer according to the present invention.

FIG. 4 is an X-ray photoelectron spectroscopy (XPS) compositional analysis of a hafnium dioxide thin film containing 4% TSA-based precursor, deposited according to the present invention.

FIG. 5 is a process flow diagram according to the present invention.

### DESCRIPTION OF THE PREFERRED EMBODIMENTS

The present invention is best understood by referring to the following detailed description and drawings. Various embodiments are discussed below with reference to the figures. However, person having ordinary skill in the art will readily understand that the details provided here in relation to the figures are for illustrative purposes only. These methods and systems may exceed the described embodiments. For example, the teachings provided herein and the requirements of specific applications may yield a variety of alternative and suitable methods for implementing any detail described herein. Thus, any method may extend beyond the particular implementations described in the following examples.

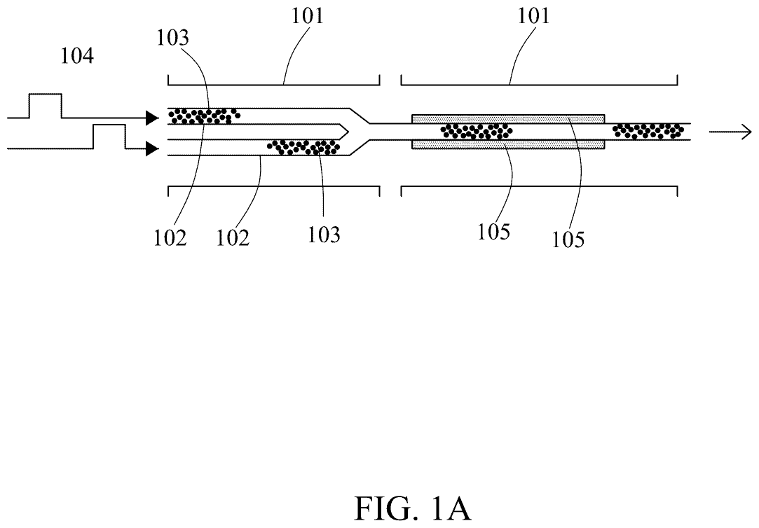

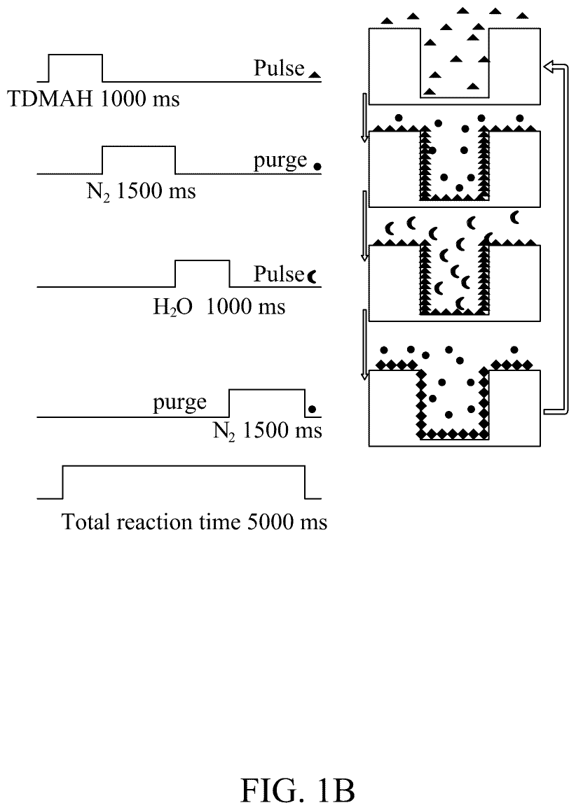

Referring to FIG. 1, which depicts a schematic diagram of an Atomic Layer Deposition (ALD) system and its underlying principles, ALD technology has recently been widely applied to nanometer-scale thin film deposition processes (e.g., high-k dielectric layers) due to its excellent thin film deposition capability. Its features include:
1. Nearly 100% step coverage;
2. Precise control of film thickness;
3. Excellent uniformity over large-area films;
4. Excellent process stability; and
5. Lower temperature processing.

These exceptional properties are attributed to ALD's unique saturated chemisorption and self-limiting deposition mechanism, which differs from traditional coating techniques. These features make ALD an advanced thin film deposition technology of great interest.

FIGS. 1A and 1B illustrate an ALD system and its process, where FIG. 1A shows a schematic view of an ALD system 100. As shown in FIG. 1A, ALD system 100 includes a reaction chamber 101. Via precursor conduit 102, a precursor 103 to be reacted is introduced into the enclosed chamber 101, in accordance with the timing and flow pattern 104, and is adsorbed onto the surface of a substrate 105 at a specific temperature, forming a desired film on the substrate surface.

FIG. 1B gives a more detailed schematic of the ALD process. Taking HfO₂ deposition as an example, in Step A, TEMAH (Tetrakis(ethylmethylamino)hafnium) is introduced for 1000 ms so that it saturates and chemisorbs onto the substrate 105 surface. In Step B, nitrogen (N₂) is purged for 1500 ms to remove excess precursor from the reaction chamber 101, leaving only one layer of TEMAH chemisorbed on the surface of substrate 105. In Step C, H₂O is introduced for 1000 ms. At this time, the substrate temperature may be raised to 150-300° C. to enable a reaction between H₂O and TEMAH to form HfO₂ on the surface of substrate 105. Then in Step D, nitrogen is again purged for 1500 ms to remove excess water and byproducts from the reaction chamber 101.

Thus, using this approach of introducing only one type of precursor at a time, each precursor and any byproducts are purged away by an inert gas such as argon (Ar) or nitrogen (N₂) after the reaction, achieving self-limited growth. The total reaction time is referred to as one ALD cycle. Repeating multiple cycles ultimately yields a metal oxide dielectric layer of a desired thickness.

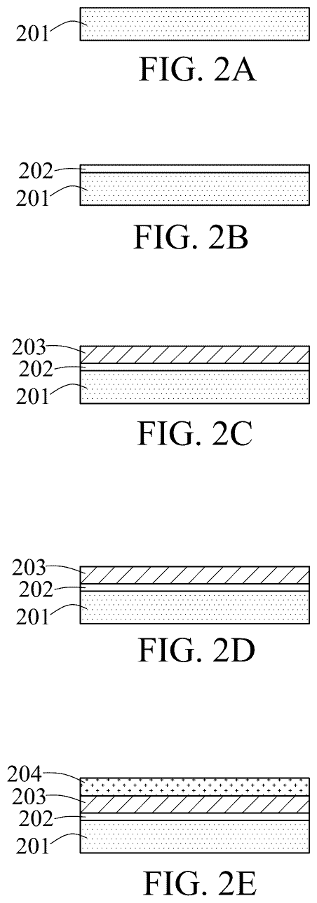

FIGS. 2A to 2E schematically show the conventional method for depositing a metal oxide dielectric layer. Referring first to FIG. 2A, a substrate 201 is provided. In nanometer-scale semiconductor processes, substrate 201 may be a silicon wafer with a planar surface, or a wafer etched with fin-type (Fin) structures, or a wafer with capacitor column structures, among other possibilities. The surface of the substrate is first cleaned to remove any loose native oxide.

Next, as shown in FIG. 2B, an ISSG process is employed on substrate 201 to form an ultrathin, dense SiO₂ layer 202. The deposition conditions for this reaction are as follows: reaction gas is oxygen or hydrogen; gas flow: O₂ at 10-30 slm, H₂ at 5-15 slm, with the O₂-to-H₂ ratio at 2:1; operating pressure <20 Torr; and a substrate temperature >1000° C.

Referring to FIG. 2C, a high-k metal oxide thin film 203 is then formed via ALD. The high-k metal oxide may be HfO₂, ZrO₂, La₂O₃, Al₂O₃, or a metal-doped ternary oxide thereof (e.g., doped with Al, Zr, Si, lanthanides), but it is not limited to these. Taking HfO₂ as an example, its precursor may be TEMAH or TDMAH, each pulse time being 0.5-2 seconds, with a substrate temperature of 25-150° C. The reaction gas can be H₂O, O₃, or O₂ plasma, with gas flow of 50-100 sccm; a substrate temperature of 150-300° C.; and an operating pressure of 10\hat{ }-2-10\hat{ }2 Torr, with each pulse time being 0.5-2 seconds.

FIG. 2D represents a rapid thermal anneal (RTA) process to optimize the structure of the metal oxide dielectric layer, further reducing leakage current and improving the crystallinity of the metal oxide. This promotes a higher dielectric constant. The RTA is conducted in an inert atmosphere such as Ar or N₂, with a gas flow of 0.5-10 slm, a pressure of 10\hat{ }-2-10\hat{ }2 Torr, a temperature of 400-900° C., and a duration less than 60 seconds.

Turning to FIG. 2E, a gate electrode material 204 is formed on the metal oxide dielectric layer 203. Generally, in nanometer-scale CMOS processes, the gate material often includes titanium nitride (TiN) or tantalum nitride (TaN) as a base layer.

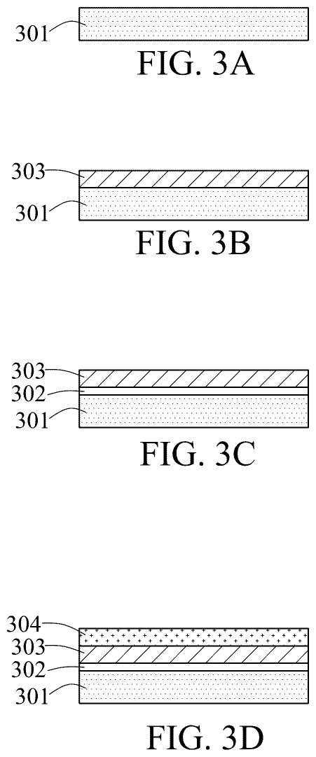

FIGS. 3A to 3D illustrates a schematic of the deposition of a metal oxide dielectric layer according to the present invention. FIG. 3A is similar to FIG. 2A, showing a substrate 301 from which the native oxide has been removed. Then, as shown in FIG. 3B, prior to depositing a dense SiO₂ layer, an ALD process introduces a metal oxide precursor containing trisilyl amine (TSA), forming a metal oxide 303 that contains a certain proportion of silicon (or SiO₂) doped within. This doping of Si into the metal oxide occurs simultaneously during the deposition step.

Next, a rapid thermal anneal is performed to re-optimize the metal oxide 303. During this step, the silicon atoms doped in the metal oxide are driven toward the interface between the substrate 301 and the metal oxide 303, forming a dense interfacial SiO₂ layer 302, as shown in FIG. 3C. A notable discovery of the present invention is that the doped silicon atoms migrate toward the substrate-oxide interface during the anneal. This invention thus removes the need for the ISSG technique to deposit SiO₂, significantly reducing complexity and manufacturing cost compared with the prior art.

Taking HfO₂ as an example, the present invention's TSA doping concentration ranges between 0.1% and 10%. One may mix a molar ratio of TSA with HfO₂ precursor TEMAH or TDMAH and deposit a silicon-doped HfO₂ film via chemical vapor deposition, or adopt an ALD approach to cyclically deposit a silicon-doped HfO₂ film until the required thickness is reached, followed by a single anneal. Alternatively, one can first perform one ALD cycle of SiO₂ using a TSA precursor and then follow with, for example, 24 ALD cycles of HfO₂ using a TEMAH precursor. By repeating such a procedure to achieve the required thickness, the resulting metal oxide 303 is effectively a multilayer structure containing some amount of SiO₂. A subsequent rapid thermal anneal yields the stratified structure shown in FIG. 3C. The RTA also optimizes the HfO₂ crystal structure; generally, HfO₂ in the orthorhombic or tetragonal phase has a higher dielectric constant.

Taking HfO₂ deposition as an example, the deposition conditions for the step shown in FIG. 3B are as follows: the TSA precursor temperature is 25-150° C., with each pulse lasting 0.5-2 seconds; the substrate temperature is 150-450° C.; the reaction gas can be H₂O, O₃, or O₂ plasma, at a flow rate of 30-200 sccm, and an operating pressure between 10\hat{ }-2 and 10\hat{ }2 Torr. If the metal oxide 303 is formed by alternating introduction of TSA and a metal oxide precursor in an ALD cycle, the conditions are similar to those described above. The RTA step has a temperature range of 300-1100° C., a duration of less than 60 seconds, an operating pressure of 10\hat{ }2-10\hat{ }-2 Torr, and uses an inert gas such as Ar or N₂ at a flow rate of 0.5-10 slm.

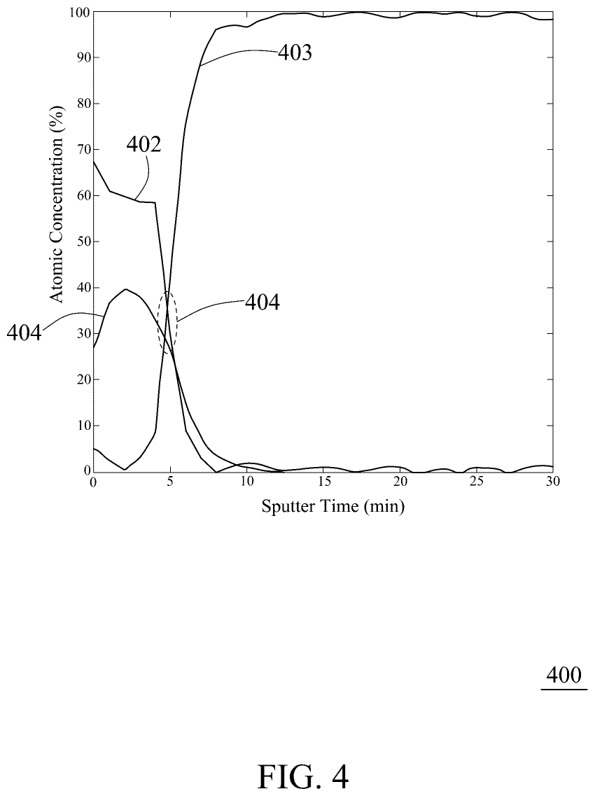

FIG. 4 shows X-ray photoelectron spectroscopy (XPS) compositional depth profiling 400 of an HfO₂ film containing 4% silicon (or SiO₂) deposited on a silicon substrate according to the present invention and then subjected to RTA. Curve 401 is the hafnium (Hf) concentration profile, 402 is the oxygen (O) concentration profile, and 403 is the silicon (Si) concentration profile. As seen in FIG. 4, at the surface of the film, the main components are hafnium and oxygen. Moving further inward, the silicon signal emerges and gradually strengthens, particularly in the elliptically labeled region 404, where the Hf signal weakens, and the Si signal grows stronger; during this time, the oxygen signal remains relatively stable. This indicates that the interfacial region is a layer of SiO₂, confirming that the present invention indeed creates an interfacial SiO₂ layer 302 between the HfO₂ (metal oxide 303) and the silicon substrate 301.

From the above description, during the deposition of a metal oxide dielectric layer using a metal oxide precursor, adding a small amount of TSA enables the formation of a high-quality interfacial SiO₂ layer between the substrate and the metal oxide dielectric layer to block the metal from diffusing into the silicon substrate and causing leakage.

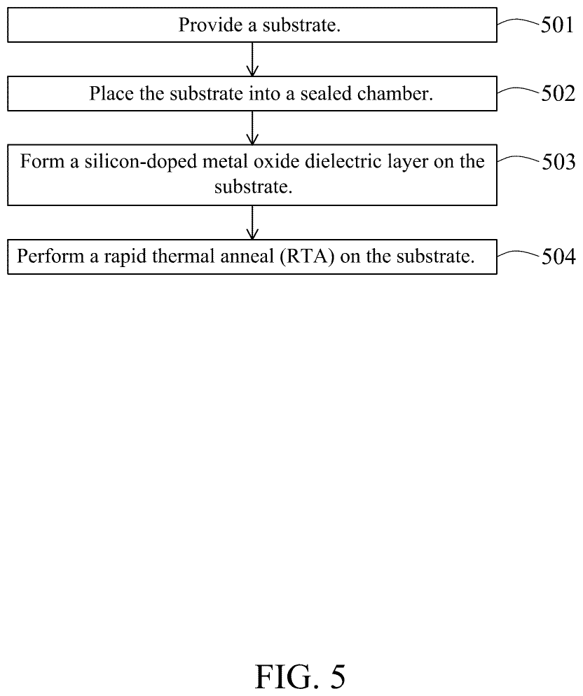

FIG. 5 is a flow diagram for forming a metal oxide dielectric layer according to the present invention. In Step 501, a substrate is provided, such as a semiconductor wafer (e.g., silicon), and any native oxide on the surface is removed. In Step 502, the substrate is placed into a sealed chamber, mainly to control the conditions during film deposition (e.g., precursor flows, inert gas flows, pressure, temperature, etc.). In Step 503, a silicon-doped metal oxide dielectric layer is formed on the substrate. In Step 504, a rapid thermal anneal is performed to optimize the metal oxide's effective dielectric constant.

Notably, the silicon doping in Step 503 uses TSA as the reactive precursor. After the RTA of Step 504, a high-quality SiO₂ interfacial layer is obtained. Step 503 can be carried out by doping the organometallic precursor with TSA, then introducing it into an environment containing an active oxygen source in a sealed chamber to form the film via standard chemical vapor deposition. Alternatively, an ALD process can be performed, in which cycles of TSA deposition of SiO₂ alternate with cycles of organometallic precursor deposition of a metal oxide. Once a preset thickness is reached, Step 504 is performed, driving the formation of a SiO₂ barrier layer between the silicon substrate and the metal oxide. Additionally, Step 504 may also optimize the crystal structure of the metal oxide. For example, in the case of HfO₂, higher temperatures can induce the orthorhombic or tetragonal phase with a higher dielectric constant, further increasing the effective dielectric constant of the (SiO₂+HfO₂) oxide dielectric layer.

1. A method for forming a metal oxide dielectric layer, comprising:
providing a substrate;
placing the substrate into a sealed chamber;
forming a silicon-doped metal oxide dielectric layer on the substrate;
performing a rapid thermal anneal on the substrate such that a silicon dioxide interfacial layer is formed between the substrate and the metal oxide dielectric layer;
wherein the silicon doping employs trisilyl amine (chemical formula N(SiH₃)₃) as a reaction precursor.

2. The method for forming a metal oxide dielectric layer according to claim 1, wherein the silicon-doped metal oxide dielectric layer is formed by doping an organometallic precursor with trisilyl amine and then introducing it into an environment containing an active oxygen source to react.

3. The method for forming a metal oxide dielectric layer according to claim 1, wherein the silicon-doped metal oxide dielectric layer is formed by an atomic layer deposition process comprising alternating cycles of depositing silicon dioxide using trisilyl amine as the precursor and depositing a metal oxide using an organometallic precursor.

4. The method for forming a metal oxide dielectric layer according to claim 1, wherein the metal oxide dielectric layer is a metal oxide or nitride.

5. The method for forming a metal oxide dielectric layer according to claim 1, wherein the metal oxide dielectric layer is selected from the group consisting of hafnium dioxide, zirconium dioxide, lanthanum oxide, and aluminum oxide.

6. The method for forming a metal oxide dielectric layer according to claim 2, wherein is the organometallic precursor tetrakis(ethylmethylamino)hafnium or tetrakis(dimethylamido)hafnium to form a hafnium dioxide metal oxide dielectric layer.

7. The method for forming a metal oxide dielectric layer according to claim 1, wherein the silicon doping concentration is between 0.1% and 10%.

8. The method for forming a metal oxide dielectric layer according to claim 1, wherein forming the silicon-doped metal oxide dielectric layer on the substrate further comprises:
introducing an active oxygen source into the sealed chamber; and
heating the substrate to a temperature between 100° C. and 450° C.

9. The method for forming a metal oxide dielectric layer according to claim 1, wherein the rapid thermal anneal temperature is between 300° C. and 1100° C.

10. The method for forming a metal oxide dielectric layer according to claim 6, wherein the hafnium dioxide has an orthorhombic or tetragonal crystal structure.

11. The method for forming a metal oxide dielectric layer according to claim 8, wherein the active oxygen source is selected from the group consisting of ozone, neutral oxygen atoms, and oxygen ions.

12. The method for forming a metal oxide dielectric layer according to claim 1, wherein the substrate is selected from the group consisting of silicon, silicon carbide, and compound semiconductors.
